(19) United States
(12) Patent Application Publication
(10) Pub. No.: US 2026/0206218 A1
(43) Pub. Date: Jul. 16, 2026

(54) SEMICONDUCTOR MEMORY DEVICE

(71) Applicant: Samsung Electronics Co., Ltd., Suwon-si (KR)

(72) Inventor: Jeonil Lee, Suwon-si (KR)

(21) Appl. No.: 19/367,074

(22) Filed: Oct. 23, 2025

(30) Foreign Application Priority Data
Jan. 8, 2025 (KR) 10-2025-0002884

(51) Int. Cl. H10B 41/27; G11C 5/06; H10B 41/35; H10D 30/01; H10D 30/67

(52) U.S. Cl. CPC H10B 41/27; G11C 5/063; H10B 41/35; H10D 30/0312; H10D 30/0411; H10D 30/6735; H10D 30/6757; H10D 30/0318; H10D 30/6728

(57) ABSTRACT

Provided is a semiconductor memory device having a gate-all-around structure, in which a first channel layer at least partially surrounds a second channel layer, and a method of manufacturing the semiconductor memory device.

### CROSS-REFERENCE TO RELATED APPLICATION

This application is based on and claims priority under 35 U.S.C. § 119 to Korean Patent Application No. 10-2025-0002884, filed on Jan. 8, 2025, in the Korean Intellectual Property Office, the disclosure of which is incorporated by reference herein in its entirety.

### BACKGROUND

The inventive concept relates to a semiconductor memory device. More specifically, the inventive concept relates to a semiconductor memory device including a gate-all-around (GAA) structure.

With the advancement of electronic technologies, down-scaling of semiconductor devices has been progressing rapidly. Accordingly, miniaturization of memory cells may be required, and existing memory cells may have limitations in maintaining high integration and reliability. Accordingly, research has been conducted to develop semiconductor memory devices with a structure that facilitates miniaturization and high integration of memory cells.

### SUMMARY

Embodiments of the inventive concept provide a semiconductor memory device with a structure that facilitates miniaturization and high integration of memory cells.

In addition, the inventive concept is not limited to embodiments disclosed herein, and may be clearly understood by those skilled in the art from the description below.

In addition, the inventive concept provides a method of manufacturing a semiconductor memory device.

According to an aspect of the inventive concept, there is provided a semiconductor memory device including a memory cell arranged on a substrate in three dimensions along a first direction, a second direction orthogonal to the first direction, and a third direction, the memory cell including a first transistor that includes a first channel layer and a second transistor that includes a second channel layer, a bit line electrically connected to a first end of the first channel layer and extending in the third direction, a selection line electrically connected to a second end of the first channel layer and extending in the third direction, a storage node directly contacting a first surface of the second channel layer and positioned adjacent to the first channel layer, and a word line at least partially surrounding the other end of the first channel layer in the first direction and the second direction between the bit line and the selection line, and extending in the first direction, wherein the word line has a cross-section that surrounds the second end of the first channel layer and the second channel layer in a ring shape in a plane defined by the first direction and the third direction, the first channel layer has a ‘C’ shape in a plane defined by the second direction and the third direction, and the storage node and the second channel layer are arranged inside the ‘C’ shape of the first channel layer.

According to another aspect of the inventive concept, there is provided a semiconductor memory device including a bit line extending in a second direction that intersects a first direction on a substrate, a first channel layer having a ‘U’ shape in a plane defined by the second direction and a third direction perpendicular to an upper surface of the substrate, the first channel layer including a horizontal extension portion that directly contacts an upper surface of the bit line and a vertical extension portion extending in the third direction from an end of the horizontal extension portion, a second channel layer inside the ‘U’ shape of the first channel layer, the second channel layer including an upper surface that is coplanar with an upper surface of the vertical extension portion and a lower surface opposite to the upper surface, a storage node including a first surface and a second surface opposite to the first surface, wherein the first surface directly contacts an upper surface of the horizontal extension portion of the first channel layer, and the second surface directly contacts the lower surface of the second channel layer, a word line extending in the first direction and at least partially surrounding a side surface of the vertical extension portion of the first channel layer in a ring shape in the first direction and the second direction, and a selection line that directly contacts the upper surface of the second channel layer and overlaps the bit line in the third direction.

According to another aspect of the inventive concept, there is provided a semiconductor memory device including a plurality of memory cells arranged on a substrate in three dimensions along a first direction, a second direction orthogonal to the first direction, and a third direction, each memory cell of the plurality of memory cells including a first transistor and a second transistor, a plurality of bit lines each extending in the third direction, a plurality of selection lines each extending in the third direction, a first channel layer included in the first transistor, a second channel layer included in the second transistor, and a storage node, wherein the first channel layer includes a vertical extension portion extending in the third direction and directly contacting one bit line of the plurality of bit lines, and a horizontal extension portion extending in the second direction from both ends of the vertical extension portion toward one selection line of the plurality of selection lines, and the horizontal extension portion is electrically connected to the one selection line, wherein the second channel layer is at least partially surrounded by the horizontal extension portion of the first channel layer, and includes a first surface directly contacting the one selection line and a second surface facing the horizontal extension portion of the first channel layer, wherein the storage node is at least partially surrounded by the horizontal extension portion of the first channel layer, and includes a first surface directly contacting the second surface of the second channel layer and a second surface facing the horizontal extension portion of the first channel layer, wherein the semiconductor memory device further includes a word line at least partially surrounding the horizontal extension portion of the first channel layer in the first direction and the second direction between the one bit line and the one selection line, and extending in the first direction, and wherein the word line has a cross-section that surrounds the horizontal extension portion of the first channel layer and the second channel layer in a ring shape in a plane defined by the first direction and the third direction.

According to another aspect of the inventive concept, there is provided a method of manufacturing a semiconductor memory device, the method including forming a trench in a mold layer disposed on a substrate, the trench including a protrusion portion extending in a first direction and protruding in a second direction intersecting the first horizontal direction, forming a liner on a sidewall of the trench, forming a first channel layer conformally deposited along a sidewall of the protrusion portion, the first channel layer including a horizontal extension portion extending in the second direction and a vertical extension portion extending in a third direction perpendicular to the first and second directions, forming a storage node at least partially filling a portion of an area at least partially surrounded by the vertical extension portion and the horizontal extension portion of the first channel layer, forming a second channel layer in a remaining portion of the area at least partially surrounded by the vertical extension portion and the horizontal extension portion of the first channel layer, forming a selection line on an exposed surface of the second channel layer and extending in the third direction, forming a word line at least partially surrounding the horizontal extension portion of the first channel layer in the first and second horizontal directions and extending in the first direction, and forming a bit line on the vertical extension portion of the first channel layer and extending in the third direction, wherein the vertical extension portion and the horizontal extension portion of the first channel layer have a ‘C’ shape in a plane defined by the second direction and the third direction.

### BRIEF DESCRIPTION OF THE DRAWINGS

Embodiments will be more clearly understood from the following detailed description taken in conjunction with the accompanying drawings in which:

FIGS. 1A, 1B, 2A, 2B, 3A, 3B, 4A, 4B, 5A, 5B, 6A, 6B, 7A, 7B, 8A, and 8B are cross-sectional views sequentially illustrating a method of manufacturing a semiconductor memory device, according to an embodiment;

FIGS. 9A, 9B, 10A, and 10B are cross-sectional views sequentially illustrating a portion of a method of manufacturing a semiconductor memory device, according to an embodiment;

FIG. 11 is a perspective view illustrating a semiconductor memory device according to an embodiment;

FIG. 12 is an equivalent circuit diagram illustrating a cell array of a semiconductor memory device according to an embodiment; and

FIGS. 13A, 13B, 14A, 14B, 15A, 15B, 16A, and 16B are cross-sectional views sequentially illustrating a method of manufacturing a semiconductor memory device, according to an embodiment.

### DETAILED DESCRIPTION OF THE EMBODIMENTS

Hereinafter, embodiments of the inventive concept will be described in detail with reference to the attached drawings. The same reference numerals will be used throughout the drawings to refer to the same or like parts, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

The embodiments may be modified in various ways and have many different embodiments, and specific embodiments are illustrated in the drawings and described in detail in the detailed description of the embodiments. However, this is not intended to limit the scope of the inventive concept to the specific embodiments, but should be understood to include various modifications, variations, equivalents, and alternatives within the sprit or scope of the inventive concept disclosed. In describing the embodiments, a detailed description of related known technologies is omitted when it is not specifically and explicitly necessary.

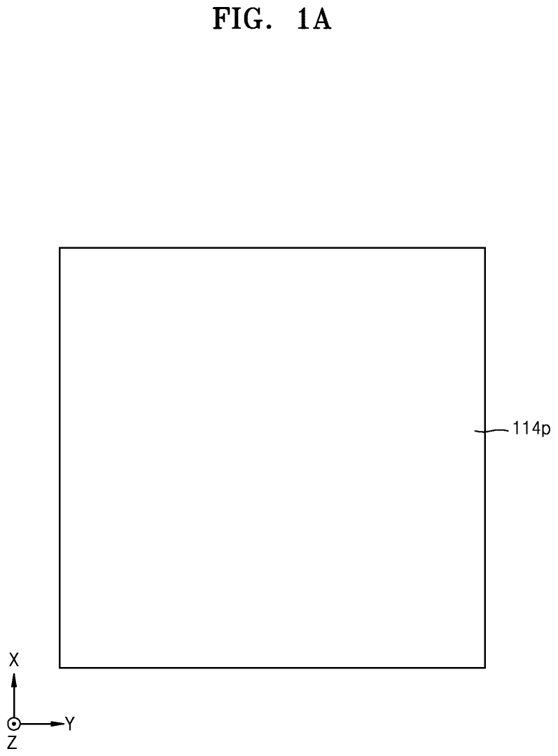

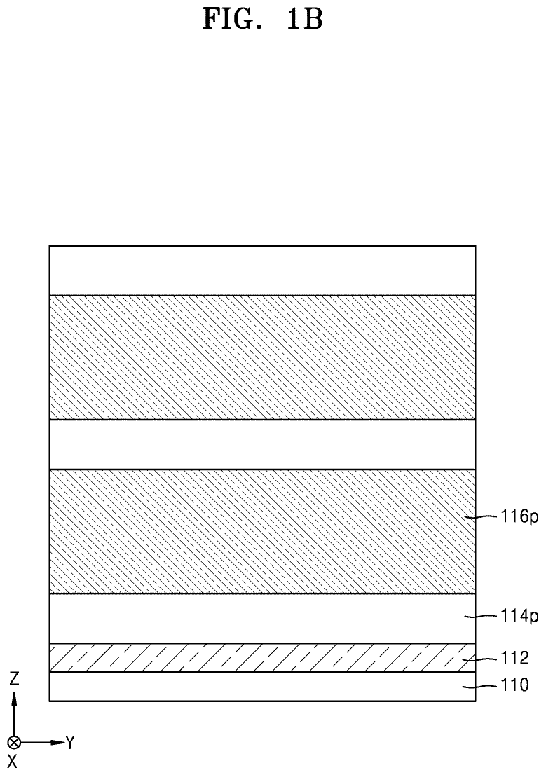

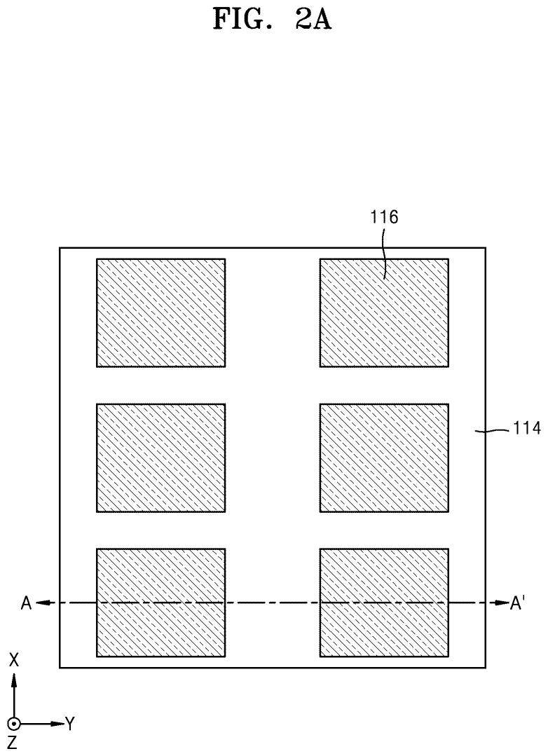

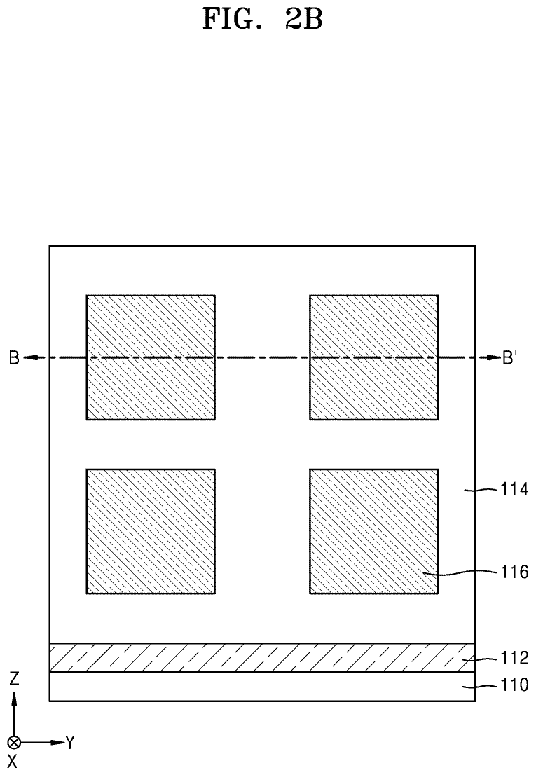

FIGS. 1A, 1B, 2A, 2B, 3A, 3B, 4A, 4B, 5A, 5B, 6A, 6B, 7A, 7B, 8A, and 8B are cross-sectional views sequentially illustrating a method of manufacturing a semiconductor memory device 100, according to an embodiment. Specifically, FIGS. 2A, 3A, 4A, 5A, 6A, 7A, and 8A are horizontal cross-sectional views taken along lines B-B′ of FIGS. 2B, 3B, 4B, 5B, 6B, 7B, and 8B, respectively, and FIGS. 2B, 3B, 4B, 5B, 6B, 7B, and 8B are vertical cross-sectional views taken along lines A-A′ of FIGS. 2A, 3A, 4A, 5A, 6A, 7A, and 8A, respectively.

Referring to FIGS. 1A and 1B, a base insulating layer 112 may be formed on a substrate 110, and a first mold layer 114p and a second mold layer 116p may be alternately stacked thereon in a vertical direction (i.e., a Z direction or third direction) perpendicular to the substrate 110. In some embodiment, the first mold layer 114p may include oxide and the second mold layer 116p may include SiN. In some embodiments, a structure formed by stacking a plurality of first mold layers 114p and a plurality of second mold layers 116p may be referred to as a mold structure.

Although FIG. 1B illustrates that the mold structure includes three first mold layers 114p spaced apart from each other in the vertical direction (the Z direction) and two second mold layers 116p spaced apart from each other in the vertical direction (the Z direction), this is only an example and embodiments of the inventive concept are not limited thereto.

The substrate 110 may include, for example, silicon (Si), such as crystalline Si, polycrystalline Si, or amorphous Si. In other embodiments, the substrate 110 may include a semiconductor element, such as germanium (Ge), or at least one of a compound semiconductor selected from silicon germanium (SiGe), silicon carbide (SiC), gallium arsenide (GaAs), indium arsenide (InAs), and/or indium phosphide (InP). In other embodiments, the substrate 110 may include a silicon-on-insulator (SOI) substrate or a germanium-on-insulator (GeOI) substrate. The substrate 110 may include a conductive region, for example, a well doped with impurities, or a structure doped with impurities.

The base insulating layer 112 may include, for example, silicon oxide, silicon nitride, silicon oxynitride, or a combination thereof. The base insulating layer 112 may include, for example, SiCN.

Referring to FIGS. 2A and 2B, a first trench (not shown) penetrating or extending into the mold structure in the vertical direction (the Z direction) may be formed. In some embodiments, after forming the first trench, the first trench may be at least partially filled with the same material as the first mold layer 114p as shown in FIGS. 1A and 1B. According to a process described above, each of the second mold layers 116p as shown in FIGS. 1A and 1B may be divided into a plurality of second mold patterns 116 spaced apart from each other in an island shape at a same vertical (Z direction) level.

Each of the second mold patterns 116 may be spaced apart from each other by a certain interval in a first horizontal direction (an X direction or first direction), and may also be spaced apart from each other by a certain interval in a second horizontal direction (a Y direction or second direction) orthogonal to the first horizontal direction (the X direction). A distance at which each of the second mold patterns 116 is spaced apart from each other in the first horizontal direction (the X direction) may be the same as or different from a distance at which each of the second mold patterns 116 is spaced apart from each other in the second horizontal direction (the Y direction). A first mold pattern 114 may at least partially fill a space between the second mold patterns 116 that are spaced apart from each other.

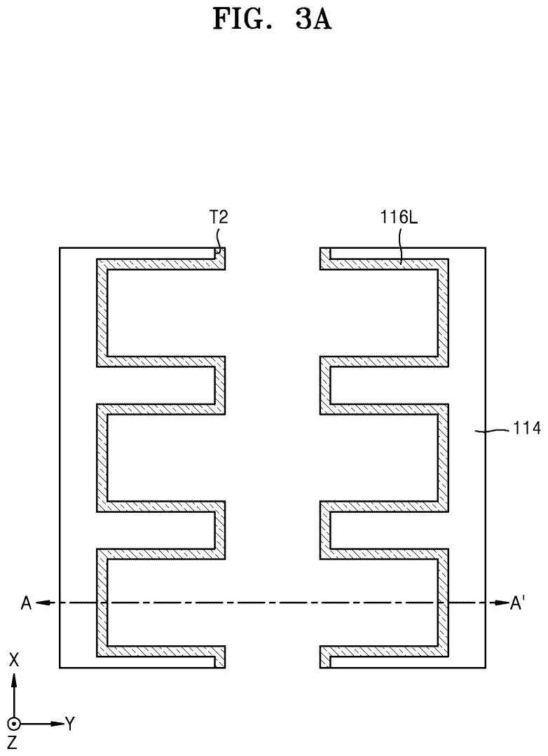

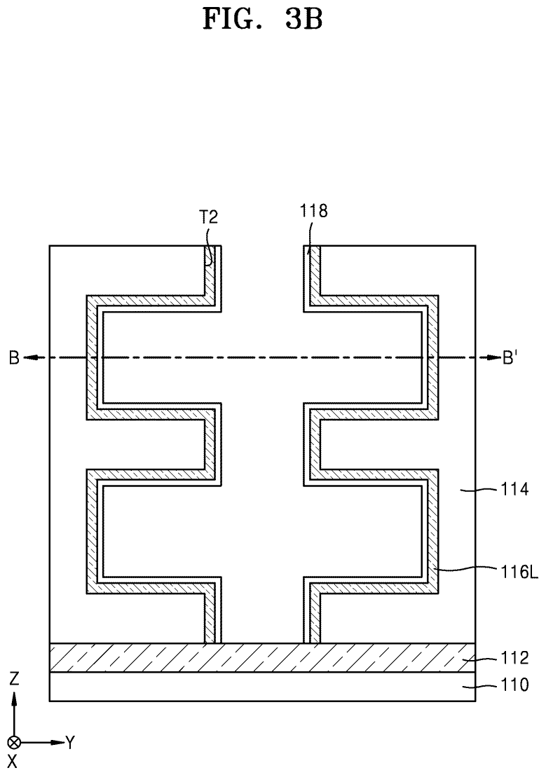

Referring to FIGS. 3A and 3B, a second trench T2 that penetrates or extends into the resulting structure of FIGS. 2A and 2B in the vertical direction (the Z direction) may be formed. In some embodiments, the second mold pattern 116 may be removed during a process of forming the second trench T2. In some embodiments, SiN included in the second mold pattern 116 may be removed by a pull back process. After the second mold pattern 116 is removed, a mold liner 116L having a thickness that conformally at least partially surrounds a sidewall of the second trench T2 may be formed. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. In some other embodiments, a portion of the second mold pattern 116 may not be removed in the pull back process and may remain as a portion of the mold liner 116L. Although omitted in FIG. 3A for convenience of illustration, referring to FIG. 3B, a mold insulating film 118 may be formed on the mold liner 116L.

The second trench T2 may be formed to extend along the first horizontal direction (the X direction) and may be formed to have a plurality of protrusion portions that protrude in the second horizontal direction (the Y direction). The protrusion portions may be formed in a left-right symmetrical shape based on extension portions of the left and the right of the second trench T2. The base insulating layer 112 may be at least partially exposed on a bottom surface of the second trench T2. In some embodiments, the second trench T2 may extend into the base insulating layer 112.

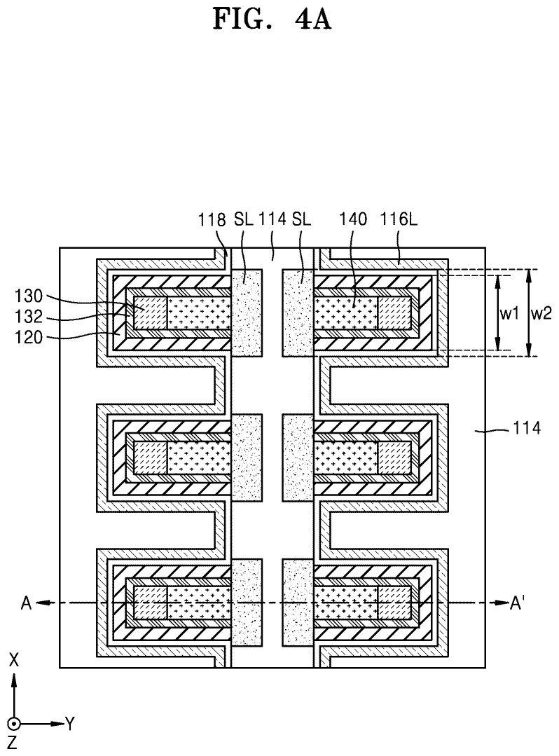

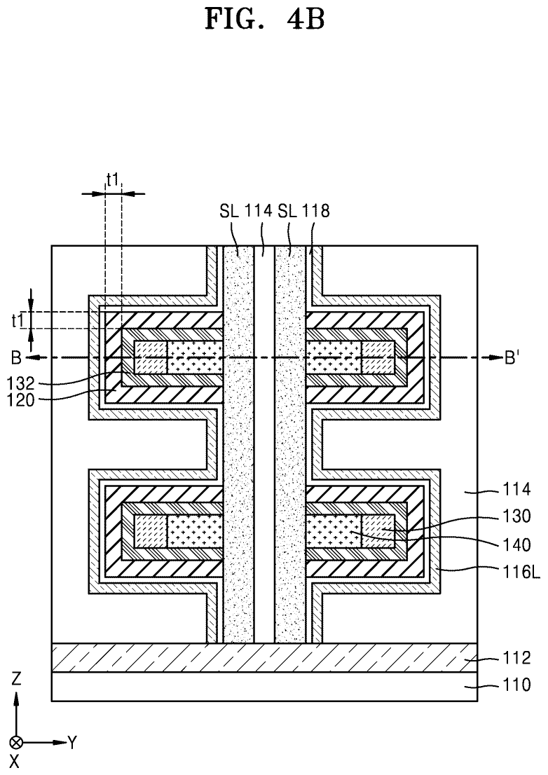

Referring to FIGS. 4A and 4B, a first channel layer 120, a storage node 130, a second channel layer 140, and a selection line SL may be formed.

Specifically, the first channel layer 120 may be formed in an approximately ‘C’ shape along a sidewall of the protrusion portion of the second trench T2 as shown in FIGS. 3A and 3B. One sidewall of the first channel layer 120 may face the sidewall of the second trench T2 as shown in FIGS. 3A and 3B, and the other sidewall of the first channel layer 120 may face the storage node 130 and the second channel layer 140. As shown in FIGS. 4A and 4B, a gate dielectric film 132 having an approximately ‘C’ shape that at least partially surrounds the sidewall of the storage node 130 and the second channel layer 140 may be between another sidewall of the first channel layer 120, and the storage node 130 and the second channel layer 140.

One sidewall of the storage node 130 may face the other sidewall of the first channel layer 120, and the other sidewall of the storage node 130 may face one sidewall of the second channel layer 140.

The storage node 130 may include a semiconductor material and/or an oxide semiconductor material. For example, the storage node 130 may include a semiconductor material doped with impurities and/or an oxide semiconductor material doped with impurities. In some embodiments, the storage node 130 may include a polysilicon material doped with n-type impurities and/or an oxide semiconductor material doped with n-type impurities. For example, the storage node 130 may include an amorphous oxide semiconductor material, a single-crystal oxide semiconductor material, a polycrystalline oxide semiconductor material, a spinel oxide semiconductor material, and/or a C-axis aligned crystalline (CAAC) oxide semiconductor material. The oxide semiconductor material may be a binary or ternary oxide semiconductor material including a first metal element, a ternary oxide semiconductor material including a first metal element and a second metal element different from each other, or a quaternary oxide semiconductor material including a first metal element, a second metal element, and a third metal element different from each other. The binary or ternary oxide semiconductor material may include, for example, one or more of zinc oxide (ZnO, ZnₓO), gallium oxide (GaO, GaₓO), tin oxide (TiO, TiₓO), zinc oxynitride (ZnON, ZnₓO_{y}N), indium zinc oxide (IZO, InₓZn_{y}O), gallium zinc oxide (GZO, GaₓZn_{y}O), tin zinc oxide (TZO, SnₓZn_{y}O), and/or tin gallium oxide (TGO, SnₓGa_{y}O), but embodiments are not limited thereto. The quaternary oxide semiconductor material may include, for example, one of indium gallium zinc oxide (IGZO), InₓGa_{y}Zn_{z}O), indium gallium silicon oxide (IGSO, InₓGa_{y}Si_{z}O), indium tin zinc oxide (ITZO, InₓSn_{y}Zn_{z}O), indium tin gallium oxide (ITGO, InₓSn_{y}Ga_{z}O), zirconium zinc tin oxide (ZZTO, ZrₓZn_{y}Sn_{z}O), hafnium indium zinc oxide (HIZO, HfₓIn_{y}Zn_{z}O), gallium zinc tin oxide (GZTO, GaₓZn_{y}Sn_{z}O), aluminum zinc tin oxide (AZTO, AlₓZn_{y}Sn_{z}O), and/or ytterbium gallium zinc oxide (YGZO, YbₓGa_{y}Zn_{z}O), but embodiments are not limited thereto.

For example, the storage node 130 may include a single layer or multiple layers of the oxide semiconductor materials.

One sidewall of the second channel layer 140 may face the other sidewall of the storage node 130, and the other sidewall of the second channel layer 140 may face one sidewall of the selection line SL. In both the vertical cross-sectional view taken along line A-A′ in FIG. 4B and the horizontal cross-sectional view taken along line B-B′ in FIG. 4A, the first channel layer 120 may have a shape that at least partially surrounds the second channel layer 140 in the ‘C’ shape.

The plurality of selection lines SL may extend in the vertical direction (the Z direction) and be spaced apart from each other along the first horizontal direction (the X direction) and the second horizontal direction (the Y direction). In some embodiments, the selection line SL may be formed at a location where the protrusion portion of the second trench T2 (see FIGS. 3A and 3B) is formed. One end of the selection line SL may be disposed at the same vertical level (Z direction) as an upper surface of the first mold pattern 114, and the other end may be disposed at the same vertical level (Z direction) as an upper surface of the base insulating layer 112.

One sidewall of the selection line SL may contact the first channel layer 120, the gate dielectric film 132, and the second channel layer 140, and the other sidewall thereof may face another adjacent selection line SL in the second horizontal direction (the Y direction). The first mold pattern 114 may be at least partially filled between the selection lines SL spaced apart from each other in the first horizontal direction (the X direction) and the second horizontal direction (the Y direction).

The gate dielectric film 132 may include at least one material selected from silicon oxide, a high-k dielectric material having a higher dielectric constant than silicon oxide, and/or a ferroelectric material. In some embodiments, the gate dielectric film 132 may have a stacked structure of a first dielectric film of silicon oxide and a second dielectric film of at least one of the high-k dielectric material and/or the ferroelectric material. For example, the high-dielectric material and the ferroelectric material may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and/or lead scandium tantalum oxide (PbScTaO).

Referring to FIG. 4A, a second width w2, which is the width of the selection line SL in the first horizontal direction (the X direction), may be greater than a first width w1, which is the width of the first channel layer 120 of the ‘C’ shape in the first horizontal direction (the X direction). At this time, in the first channel layer 120 that includes one extension portion in the first horizontal direction (the X direction) and two extension portions facing each other in the second horizontal direction (the Y direction), the first width w1 of the first channel layer 120 may mean a distance between second surfaces of the two extension portions in the second horizontal direction (the Y direction), in which the two extension portions in the horizontal direction have first surfaces facing each other and second surfaces opposite to the first surfaces, respectively. In some other embodiments, the second width w2 may be equal to the first width w1.

Referring to FIG. 4B, a thickness of the first channel layer 120 in the second horizontal direction (the Y direction) and a thickness of the first channel layer 120 in the vertical direction (the Z direction) may be equal to each other with a first thickness t1. In some embodiments, the first channel layer 120 may be formed by an atomic layer deposition (ALD) method, wherein the thickness of the first channel layer deposited along the sidewall of the second trench T2 as shown in FIGS. 3A and 3B may be constant.

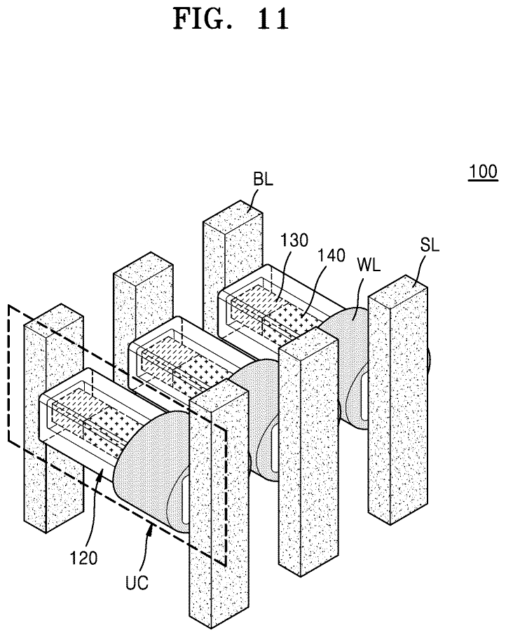

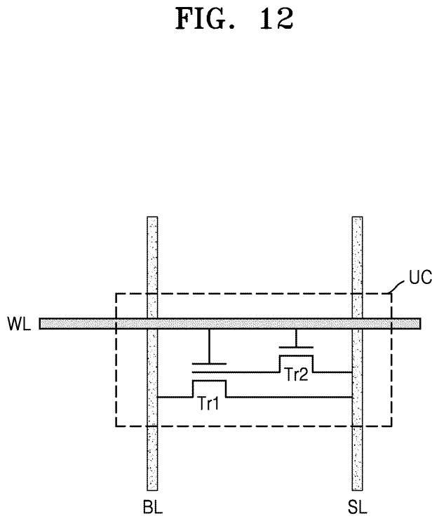

In some embodiments, the first channel layer 120 may be a channel layer of a first transistor Tr1 as shown in FIG. 12, and the first transistor Tr1 may be an n-channel metal oxide semiconductor (NMOS) transistor. The second channel layer 140 may be a channel layer of a second transistor Tr2 as shown in FIG. 12, and the second transistor Tr2 may be the NMOS transistor or a p-channel MOS (PMOS) transistor. The first transistor Tr1 may include a read transistor, and the second transistor Tr2 may include a write transistor. The relationship between the first transistor Tr1 and the second transistor Tr2 will be described in detail below with reference to FIGS. 11 and 12.

The first channel layer 120 and the second channel layer 140 may include a semiconductor material. In some embodiments, the first channel layer 120 and the second channel layer 140 may include polysilicon or a two-dimensional (2D) material semiconductor.

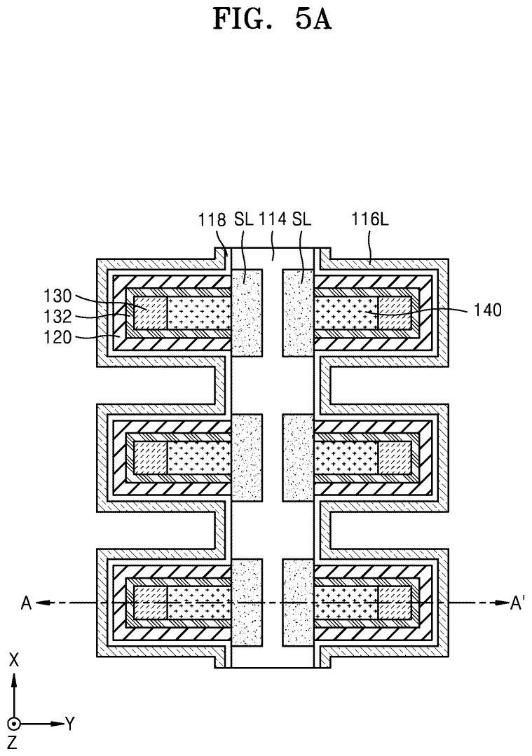

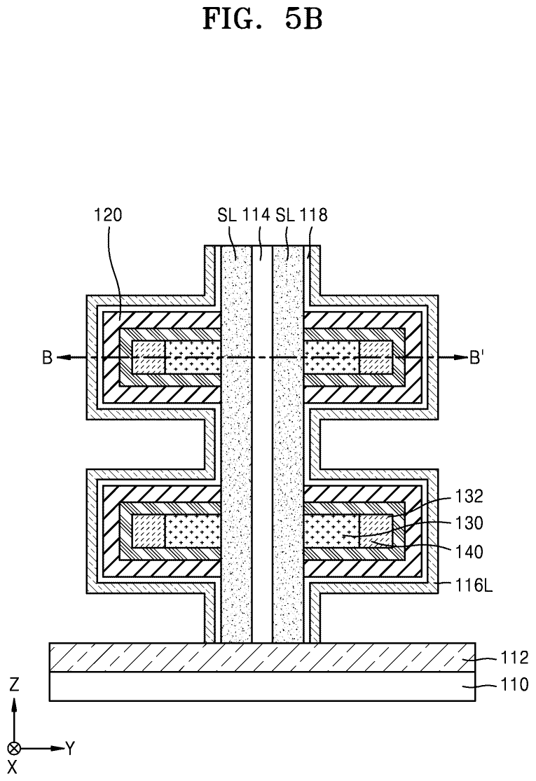

Referring to FIGS. 5A and 5B, a portion of the first mold pattern 114 as shown in FIGS. 4A and 4B may be removed. In some embodiments, the first mold pattern 114 as shown in FIGS. 4A and 4B may be removed by an etching process. According to the etching process, the mold liner 116L formed along the sidewall of the second trench T2 as shown in FIGS. 3A and 3B and the upper surface of the base insulating layer 112 may be at least partially exposed to the outside.

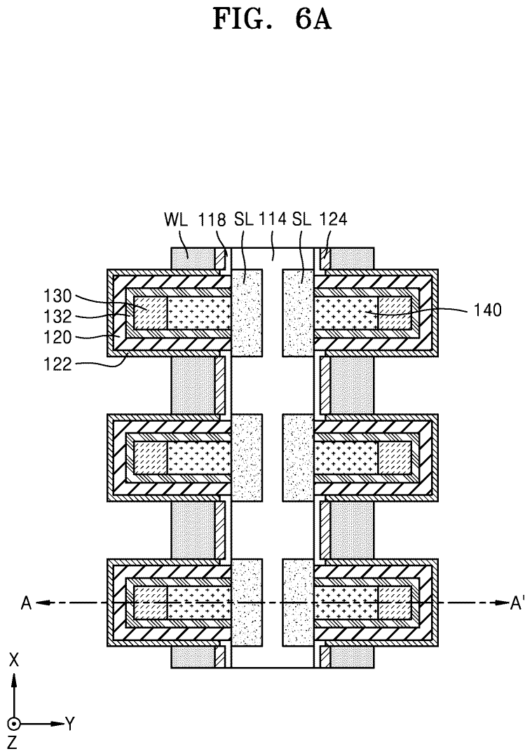

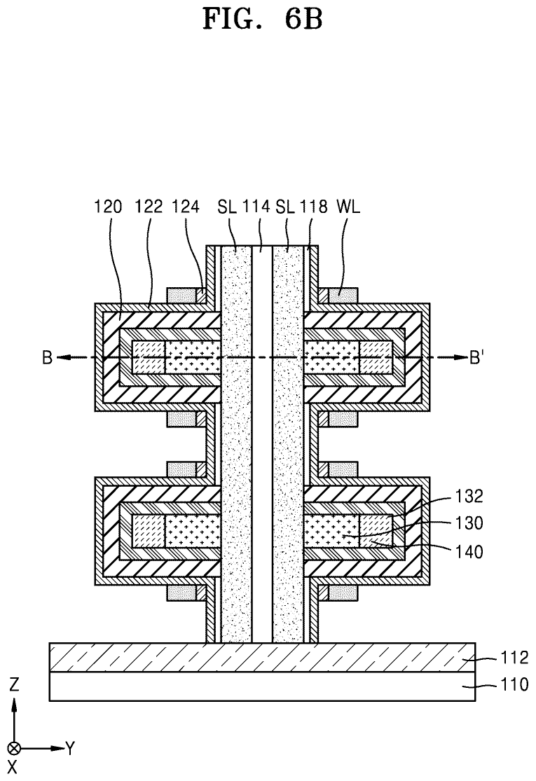

Referring to FIGS. 6A and 6B, after removing the mold liner 116L and then removing a portion of the mold insulating film 118, a cover insulating layer 122 that covers the sidewalls of the first channel layer 120 in the ‘C’ shape with a conformal thickness may be formed. The term “covers” (or “covering,” or like terms), as may be used herein, is intended to broadly refer to an element, structure or layer that is on or over another element, structure or layer, either directly or with one or more other intervening elements, structures or layers therebetween. Next, a word line WL may be formed that surrounds at least a portion of the protrusion portion of the second trench T2 as shown in FIGS. 3A and 3B. The word line WL may surround at least the portion of the protrusion portion of the second trench T2 as shown in FIGS. 3A and 3B in the form of GAA as shown in FIG. 11. In some embodiments, an insulating liner 124 may be between the word line WL and the cover insulating layer 122.

Referring to FIGS. 6A and 6B together with FIG. 11, the word line WL may extend in the first horizontal direction (the X direction) and may at least partially surround the second channel layer 140, while the selection line SL may extend in the vertical direction (the Z direction) with respect to the substrate 110. In some embodiments, the word line WL may have a cross-section that at least partially surrounds the first channel layer 120 and the second channel layer 140 in a ring shape in a plane defined by the first horizontal direction (the X direction) and the vertical direction (the Z direction). However, although not shown in the drawing, in some other embodiments, the word line WL may extend in the first horizontal direction (X direction) and at least partially surround only upper surfaces of the first channel layer 120 and the second channel layer 140. In other embodiments, the word line WL may extend in the first horizontal direction (the X direction) and at least partially surround upper and lower portions of the first channel layer 120 and the second channel layer 140 in the form of a sandwich.

The word line WL may include doped polysilicon, a metal, a conductive metal nitride, a conductive metal silicide, or a combination thereof. For example, the word line WL may include, but is not limited thereto, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof.

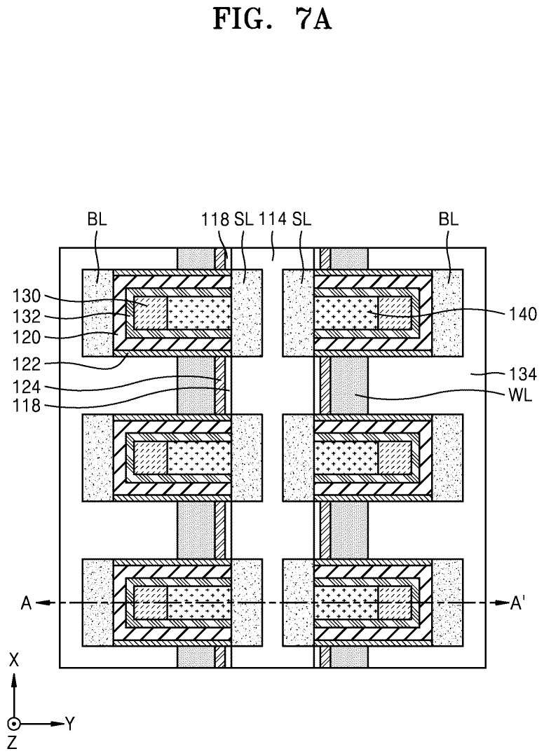

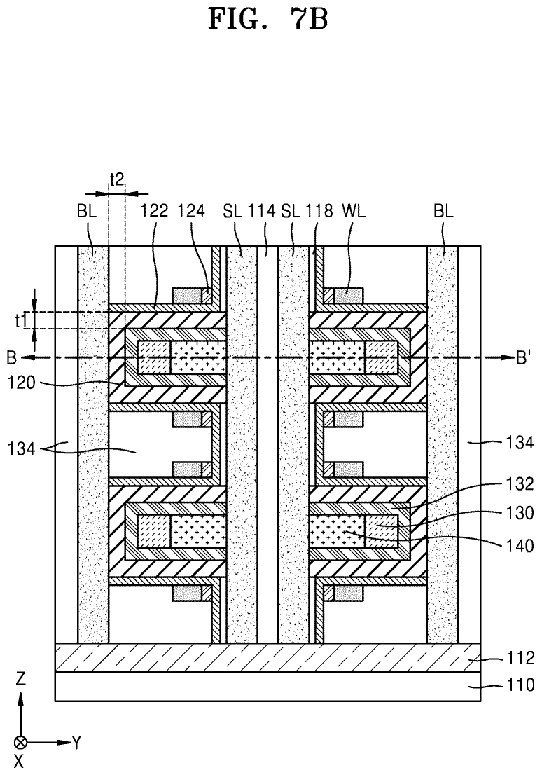

Referring to FIGS. 7A and 7B, a remaining space may be at least partially filled with a mold insulating layer 134, and a portion of the mold insulating layer 134 may be removed to form a bit line BL that contacts one sidewall of the first channel layer 120.

The plurality of bit lines BL may extend in the vertical direction (the Z direction) and be spaced apart from each other along the first horizontal direction (the X direction) and the second horizontal direction (the Y direction). In some embodiments, the bit line BL may be formed at a position such that the first channel layer 120 is between the bit line BL and the selection line SL. That is, the extension portion of the first horizontal direction (the X direction) of the first channel layer 120 may contact the bit line BL. In some embodiments, a width of the bit line BL in the first horizontal direction (the X direction) may be greater than the first width w1 as shown in FIG. 4A of the first channel layer 120.

Referring to FIG. 7A, the width of the bit line BL in the first horizontal direction (the X direction) is illustrated as being the same as a width of the selection line SL in the first horizontal direction (the X direction), but embodiments of the inventive concept are not limited thereto.

Referring to FIG. 7B, the first channel layer 120 may have the first thickness t1 in the vertical direction (the Z direction) and have a second thickness t2 in the second horizontal direction (the Y direction). Referring to FIG. 7B together with FIG. 4A, the first channel layer 120 may be formed with the same thickness in all directions as shown in FIG. 4B, but in a process of etching a portion of the mold insulating layer 134 to form the bit line BL, a portion of the extension portion of the first channel layer 120 in the vertical direction (the Z direction) may be etched together. Therefore, the second thickness t2 of FIG. 7B may be less than the first thickness t1 of FIGS. 7B and 4B. However, embodiments of the inventive concept are not limited thereto. In some other embodiments, the first channel layer 120 may not be etched during the etching process of the portion of the mold insulating layer 134, so that the second thickness t2 may maintain the same thickness as the first thickness t1.

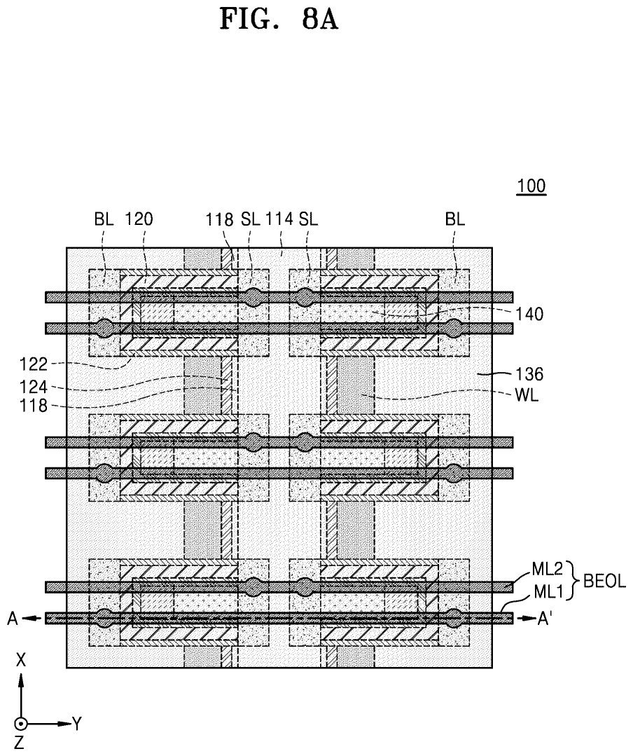

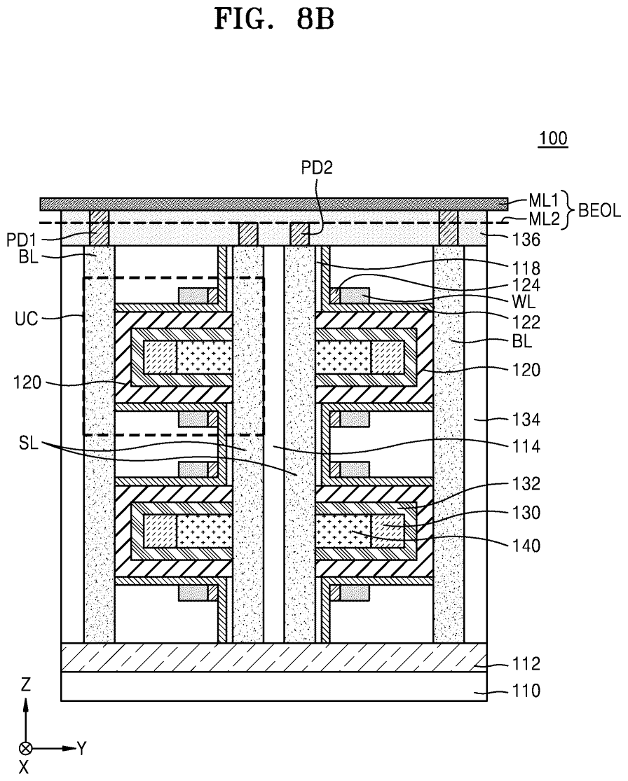

Referring to FIGS. 8A and 8B, an upper insulating layer 136 may be formed on the resulting structure of FIGS. 7A and 7B, and a portion of the upper insulating layer 136 may be removed to form a plurality of word line pads PD1 and PD2. The plurality of word line pads PD1 and PD2 may include a first pad PD1 and a second pad PD2.

In some embodiments, one end of the first pad PD1 may be electrically connected to the bit line BL and the other end may be electrically connected to a first metal line ML1, and one end of the second pad PD2 may be electrically connected to the selection line SL and the other end may be connected to a second metal line ML2.

In FIG. 8B, the first metal line ML1 is illustrated as being arranged at a higher vertical level (Z direction) than the second metal line ML2, but this is to simultaneously illustrate the first metal line ML1 and the second metal line ML2 on a vertical cross-section view taken along line A-A′ of FIG. 8A. The first metal line ML1 may be arranged at the same vertical level (Z direction) as the second metal line ML2. In addition, a vertical height relative to the substrate being a base plane (Z direction) of the first pad PD1 may be the same as that of the second pad PD2, for the same reason as above. In addition, the first metal line ML1 and the second metal line ML2 may each extend in a direction perpendicular to a direction of the word line WL in a plan view. For example, as illustrated in FIG. 8A, the first metal line ML1 and the second metal line ML2 may be spaced apart from each other in the first horizontal direction (the X direction) and may extend in the second horizontal direction (the Y direction), and the word line WL may extend in the first horizontal direction (the X direction).

The semiconductor memory device 100 having a three-dimensional structure may be manufactured through the processes described above. In some embodiments, the first metal line ML1 and the second metal line ML2 may constitute a back end of line (BEOL) of the semiconductor memory device 100.

The semiconductor memory device 100 according to embodiments of the inventive concept may include a plurality of unit cells UC that are arranged three-dimensionally along the first horizontal direction (the X direction), the second horizontal direction (the Y direction), and the vertical direction (the Z direction), and thus may have a high memory capacity. Further, in the semiconductor memory device 100, the first channel layer 120 of the first transistor Tr1 in FIG. 12 may at least partially surround the second channel layer 140 of the second transistor Tr2 in FIG. 12 in the ‘C’ shape, and information may be stored in the storage node 130 instead of a capacitor, so the integration of the device may be improved. In addition, the semiconductor memory device 100 may have the bit line BL and the selection line SL extending in the vertical direction (the Z direction) perpendicular to the substrate 110, and have the word line WL of the GAA structure horizontally arranged between the bit line BL and the selection line SL, so the semiconductor memory device 100 may have excellent gate controllability.

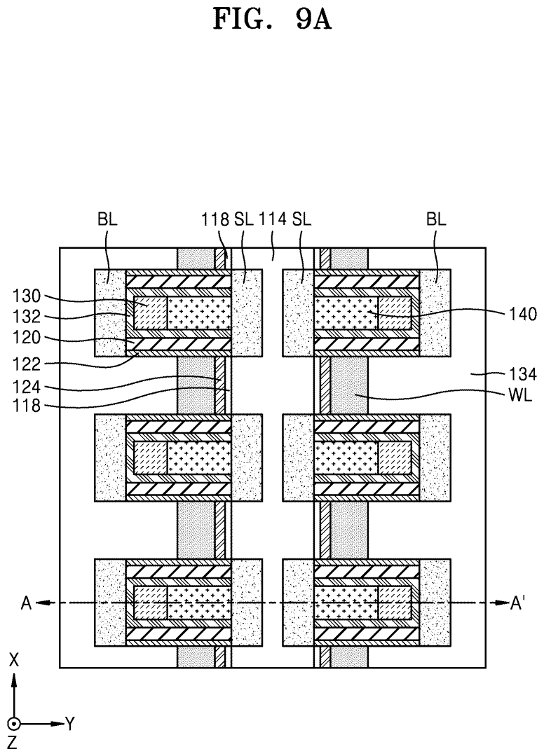

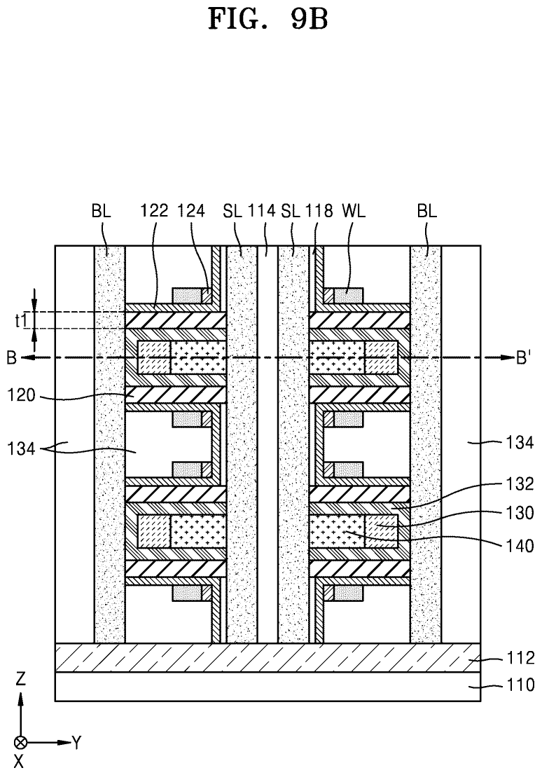

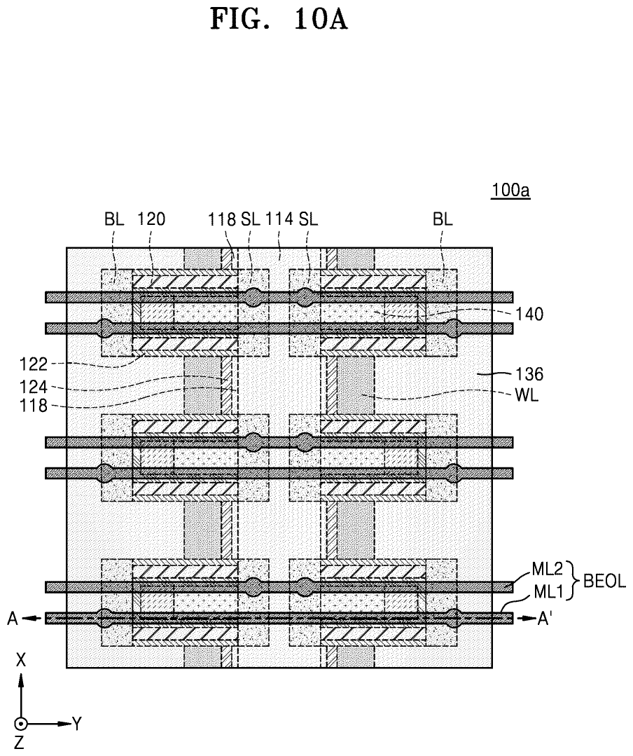

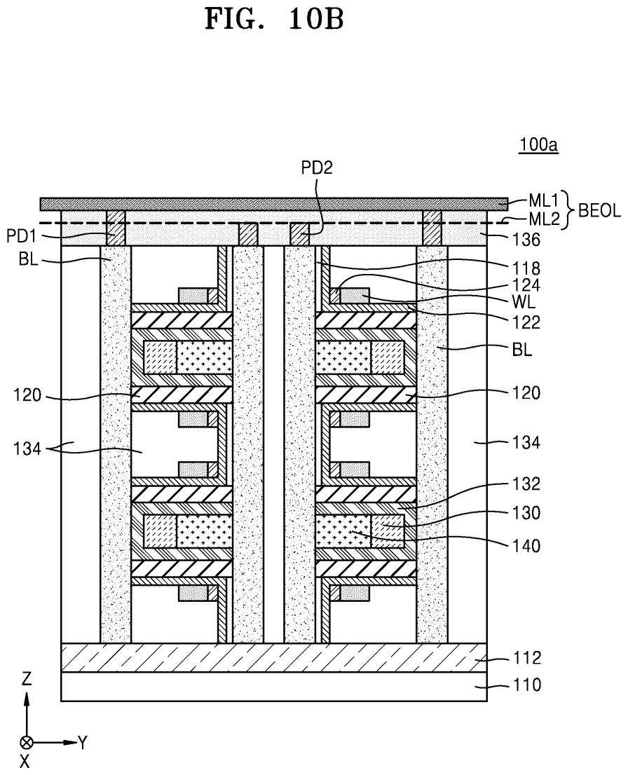

FIGS. 9A, 9B, 10A, and 10B are cross-sectional views sequentially illustrating a portion of a method of manufacturing a semiconductor memory device 100a, according to an embodiment.

Specifically, FIGS. 9A and 10A are horizontal cross-sectional views taken along line B-B′ of FIGS. 9B and 10B, and FIGS. 9B and 10B are vertical cross-sectional views taken along line A-A′ of FIGS. 9A and 10A, respectively. In the method of manufacturing the semiconductor memory device 100a, the processes described with reference to FIGS. 1A, 1B, 2A, 2B, 3A, 3B, 4A, 4B, 5A, 5B, 6A, and 6B may be performed in the same manner as in the semiconductor memory device 100 as shown in FIGS. 8A and 8B, and only the processes described with reference to FIGS. 7A, 7B, 8A, and 8B are different, so duplicated descriptions will be omitted and only portions where there are differences in process and structure will be described.

Referring to FIGS. 9A and 9B, the remaining space in the resulting structure of FIGS. 6A and 6B may be at least partially filled with the mold insulating layer 134, and a portion of the mold insulating layer 134 may be removed to form a plurality of bit lines BL extending in the vertical direction (the Z direction) and spaced apart from each other in the first horizontal direction (the X direction) and the second horizontal direction (the Y direction).

In some embodiments, during the process of removing the portion of the mold insulating layer 134 prior to forming the bit line BL, a portion of the first channel layer 120 may be removed together. Specifically, the extension portion of the first horizontal direction (the X direction) of the first channel layer 120 may be removed.

Accordingly, from the first channel layer 120 shown in FIGS. 6A and 6B, which includes the cross-section of the ‘C’ shape that includes the extension portion of the first horizontal direction (the X direction) and a pair of extension portions of the second horizontal direction (the Y direction) extending in the second horizontal direction (the Y direction) from both ends of the extension portion of the first horizontal direction (the X direction) toward the selection line SL, only the pair of extension portions of the second horizontal direction (the Y direction) spaced apart from each other may be left as a result of performing the process described with reference to FIGS. 9A and 9B. As a result, each end of the pair of extension portions of the second horizontal direction (the Y direction) may be vertically (Z direction) electrically connected to the bit line BL.

Referring to FIG. 9A, the width of the bit line BL in the first horizontal direction (the X direction) is illustrated as being the same as a width of the selection line SL in the first horizontal direction (the X direction), but embodiments of the inventive concept are not limited thereto.

Referring to FIGS. 10A and 10B, the upper insulating layer 136 may be formed on the resulting structure of FIGS. 9A and 9B, and the portion of the upper insulating layer 136 may be removed to form a plurality of word line pads PD1 and PD2. The plurality of word line pads PD1 and PD2 may include the first pad PD1 and the second pad PD2.

In some embodiments, one end of the first pad PD1 may be electrically connected to the bit line BL and the other end may be electrically connected to a first metal line ML1, and one end of the second pad PD2 may be connected to the selection line SL and the other end may be connected to a second metal line ML2.

The semiconductor memory device 100a having a three-dimensional structure may be manufactured through the processes mentioned above. A detailed description with respect to the first and second metal lines ML1 and ML2, the first and second pads PD1 and PD2, and the upper insulating layer 136 is the same as that described with reference to FIGS. 8A and 8B and thus may be omitted. In addition, similar to the semiconductor memory device 100 as shown in FIGS. 8A and 8B, the first metal line ML1 and the second metal line ML2 of the semiconductor memory device 100a may each extend in the direction perpendicular to the word line WL in a plan view. For example, as illustrated in FIG. 10A, the first metal line ML1 and the second metal line ML2 may be spaced apart from each other in the first horizontal direction (the X direction) and may extend in the second horizontal direction (the Y direction), and the word line WL may extend in the first horizontal direction (the X direction).

FIG. 11 is a perspective view illustrating the semiconductor memory device 100 (and 100a) according to an embodiment. FIG. 12 is an equivalent circuit diagram illustrating a cell array of the semiconductor memory device 100 (and 100a) according to an embodiment.

A cross-section of the unit cell UC illustrated in the perspective view of FIG. 11 may correspond to the cross-section of the unit cell UC of FIGS. 8B and 10B, and a circuit diagram of the unit cell UC illustrated in the perspective view of FIG. 11 may correspond to the circuit diagram of the unit cell UC of FIG. 12.

Below, the equivalent circuit diagram of a semiconductor memory device may be described with reference to FIGS. 11 and 12.

The semiconductor memory device may include a plurality of unit cells UC, and FIG. 12 illustrates one unit cell UC as an example. The unit cell UC may include a pair of transistors, for example, the first transistor Tr1 and the second transistor Tr2. In some embodiments, each of the first transistor Tr1 and the second transistor Tr2 may include a field effect transistor (FET).

In some embodiments, a channel layer of the first transistor Tr1 may correspond to the first channel layer 120 of FIGS. 8A, 8B, 10A, 10B, and 11, and a channel layer of the second transistor Tr2 may correspond to the second channel layer 140 of FIGS. 8A, 8B, 10A, 10B, and 11.

Each unit cell UC included in the semiconductor memory device may operate as a dynamic random access memory (DRAM) cell in which a write operation for storing information and a read operation for reading information are performed. The unit cell UC may store information in the storage node 130 as shown in FIG. 11 instead of a capacitor. The semiconductor memory device including a plurality of unit cells UC may be referred to as a DRAM device on a floating gate substrate. The semiconductor memory device including the plurality of unit cells UC may include a volatile semiconductor memory device.

In some embodiments, the word line WL may be electrically connected to a gate line of each of the first transistor Tr1 and the second transistor Tr2 included in the plurality of unit cells UC. In some embodiments, a plurality of word lines WL may extend in a first horizontal direction and be spaced apart from each other in a second horizontal direction orthogonal to the first horizontal direction. Although not shown in FIG. 12, the gate line of each of the first transistor Tr1 and the second transistor Tr2 may extend in a vertical direction orthogonal to the first horizontal direction and the second horizontal direction.

One end of a channel region of the first transistor Tr1 may be electrically coupled to the bit line BL, and the other end thereof may be electrically coupled to the selection line SL. One end of the channel region of the second transistor Tr2 may be electrically coupled to the storage node 130 as shown in FIG. 11, and the other end thereof may be electrically coupled to the selection line SL. In some embodiments, each of the bit line BL and the selection line SL may extend in the second horizontal direction.

The second transistor Tr2 may store charge in the storage node 130. Depending on the amount of charge stored in the storage node 130, a threshold voltage of the first transistor Tr1 in which the storage node 130 functions as a floating gate may change, and depending on the threshold voltage of the first transistor Tr1 determined by the amount of charge stored in the storage node 130, information stored in the unit cell UC may be read as ‘0’ or ‘1’. For example, the second transistor Tr2 of one unit cell UC may be selected by one word line WL and one bit line BL to store charge in the storage node 130. Additionally, the first transistor Tr1 of one unit cell UC may be selected by one word line WL, one bit line BL, and one selection line SL, and depending on the threshold voltage of the first transistor Tr1 determined by the amount of charge stored in the storage node 130, information stored in the unit cell UC may be read. The first transistor Tr1 may be referred to as the read transistor, and the second transistor Tr2 may be referred to as the write transistor. The unit cell UC may be referred to as a 2T memory cell.

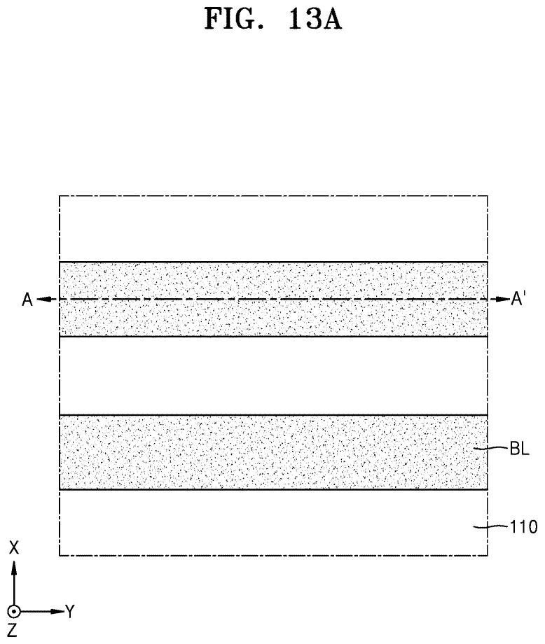

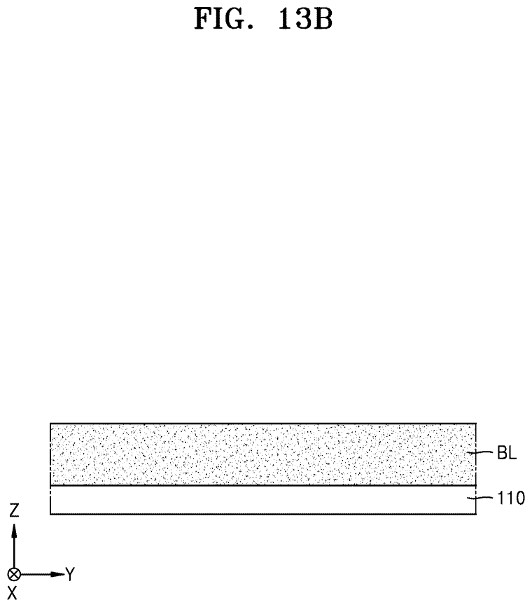

FIGS. 13A, 13B, 14A, 14B, 15A, 15B, 16A, and 16B are cross-sectional views sequentially illustrating a method of manufacturing a semiconductor memory device 100b, according to an embodiment. Specifically, FIGS. 13A, 14A, 15A, and 16A are horizontal cross-sectional views taken along lines B-B′ of FIGS. 13B, 14B, 15B, and 16B, and FIGS. 13B, 14B, 15B, and 16B are vertical cross-sectional views taken along lines A-A′ of FIGS. 13A, 14A, 15A, and 16A.

It will be understood that components described in the method of manufacturing the semiconductor memory device 100b described with reference to FIGS. 13A, 13B, 14A, 14B, 15A, 15B, 16A, and 16B are not mutually exclusive with components described in the method of manufacturing the semiconductor memory devices 100 and 100a described with reference to FIGS. 1A, 1B, 2A, 2B, 3A, 3B, 4A, 4B, 5A, 5B, 6A, 6B, 7A, 7B, 8A, and 8B and FIGS. 9A, 9B, 10A, and 10B, and that components having the same reference numerals are the same components. The semiconductor memory device 100b described with reference to FIGS. 13A, 13B, 14A, 14B, 15A, 15B, 16A, and 16B may have structural differences rather than functional differences between components, compared to the semiconductor memory device 100 described with reference to FIGS. 1A, 1B, 2A, 2B, 3A, 3B, 4A, 4B, 5A, 5B, 6A, 6B, 7A, 7B, 8A, and 8B and the semiconductor memory device 100a described with reference to FIGS. 9A, 9B, 10A, and 10B. Specifically, the semiconductor memory devices 100 and 100a may have a 3D structure, whereas the semiconductor memory device 100b described with reference to FIGS. 13A, 13B, 14A, 14B, 15A, 15B, 16A, and 16B may have a vertical channel transistor (VCT) structure. Hereinafter, duplicate descriptions with respect to the same components will be simplified or omitted, and the structural differences between the semiconductor memory device 100 of FIGS. 1A, 1B, 2A, 2B, 3A, 3B, 4A, 4B, 5A, 5B, 6A, 6B, 7A, 7B, 8A, and 8B and the semiconductor memory device 100a of FIGS. 9A, 9B, 10A, and 10B will be mainly described.

Referring to FIGS. 13A and 13B, the plurality of bit lines BL may be formed on the substrate 110. Each of the plurality of bit lines BL may be spaced apart from each other in the first horizontal direction (the X direction) and extend in the second horizontal direction (the Y direction).

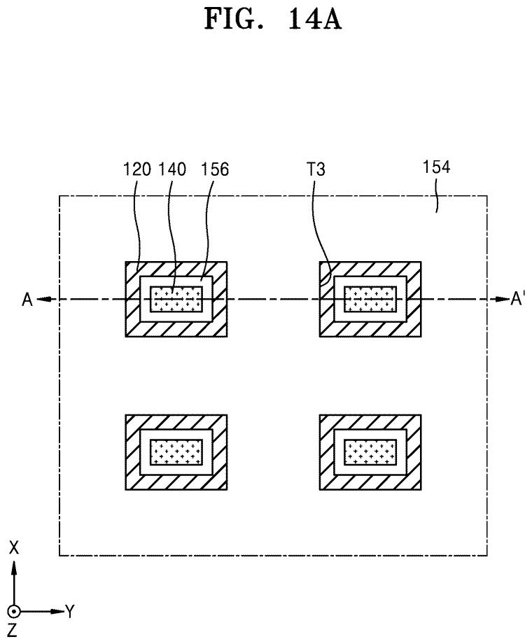

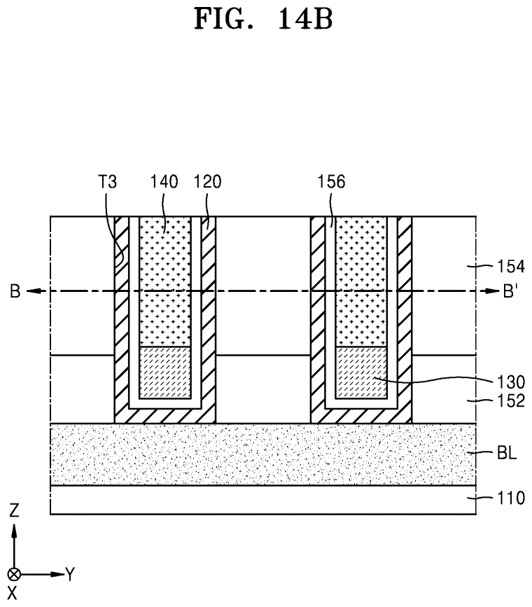

Referring to FIGS. 14A and 14B, a first mold insulating layer 152 and a second mold insulating layer 154 may be formed on the bit line BL, a third trench T3 may be formed by removing portions of the first mold insulating layer 152 and the second mold insulating layer 154, and then the first channel layer 120 may be formed that at least partially covers a sidewall and a bottom surface of the third trench T3 with a conformal thickness.

Referring to FIG. 14B, the third trench T3 may be formed to have a cross-section of a ‘U’ shape, and an upper surface of the bit line BL may be at least partially exposed by the formation of the third trench T3. The first channel layer 120 may formed along the third trench T3, the first channel layer 120 may be deposited to have a cross-section of the ‘U’ shape similar to that of the third trench T3.

After forming the first channel layer 120, the storage node 130 that fills at least a portion of the remaining space of the third trench T3 may be formed, and then the second channel layer 140 that at least partially fills the entire remaining space of the third trench T3 may be formed on the storage node 130. In some embodiments, a gate dielectric film 156 may be between the first channel layer 120 and the storage node 130 and between the first channel layer 120 and the second channel layer 140. In some embodiments, an upper surface of the second channel layer 140 may be positioned at the same vertical level (Z direction) as an upper surface of the second mold insulating layer 154.

Referring to FIG. 14A, which is a horizontal cross-sectional view taken along line B-B′ of FIG. 14B, the second channel layer 140 may be arranged inside the first channel layer 120 that at least partially surrounds the third trench T3 in a rectangular shape, and four side surfaces of the second channel layer 140 may be at least partially surrounded by the gate dielectric film 156 on all sides.

The first channel layer 120 may be formed to at least partially surround the second channel layer 140 in the ‘U’ shape base on the vertical cross-section, which may be structurally similar to the semiconductor memory device 100 of FIGS. 8A and 8B in which the first channel layer 120 is formed to at least partially surround the second channel layer 140 in the ‘C’ shape based on the vertical cross-section.

In some embodiments, the first channel layer 120 may be a channel layer of the first transistor Tr1 as shown in FIG. 12, and the second channel layer 140 may be a channel layer of the second transistor Tr2 as shown in FIG. 12.

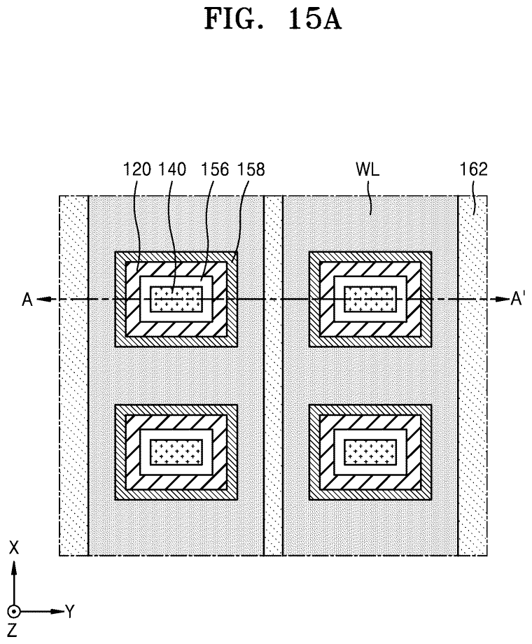

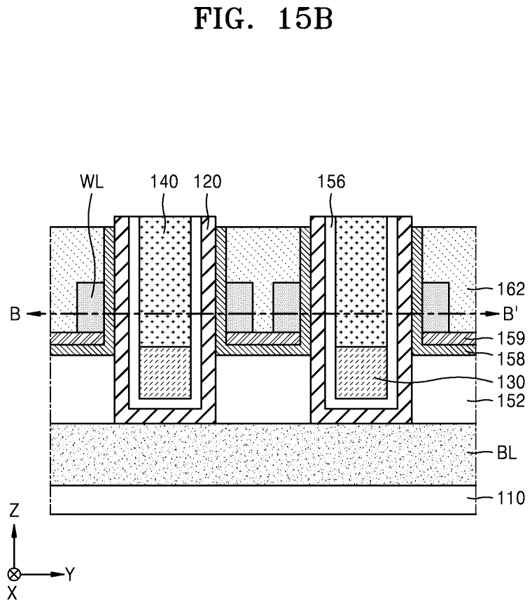

Referring to FIGS. 15A and 15B, the second mold insulating layer 154 as shown in FIGS. 14A and 14B may be removed, a cover insulating layer 158 may be formed that at least partially covers an upper surface of the first mold insulating layer 152 and side surfaces of the first channel layer 120. Then, the word line WL at least partially surrounding the third trench T3 as shown in FIGS. 12A and 12B may be formed. Next, a third mold insulating layer 162 may be formed to at least partially surround the word line WL and the cover insulating layer 158. In some embodiments, an insulating liner 124 may be additionally arranged between the word line WL and the cover insulating layer 158. In some embodiments, the third mold insulating layer 162 may include substantially the same material as the second mold insulating layer 154 as shown in FIGS. 14A and 14B.

The word line WL may be formed in the form of GAA that at least partially surrounds the first channel layer 120 in all directions at a predefined height that is a vertical level lower than an upper surface of a vertical extension portion of the first channel layer 120 relative to the substrate 110 as shown in FIG. 15B, and the word line WL may correspond to the word line WL of FIG. 12.

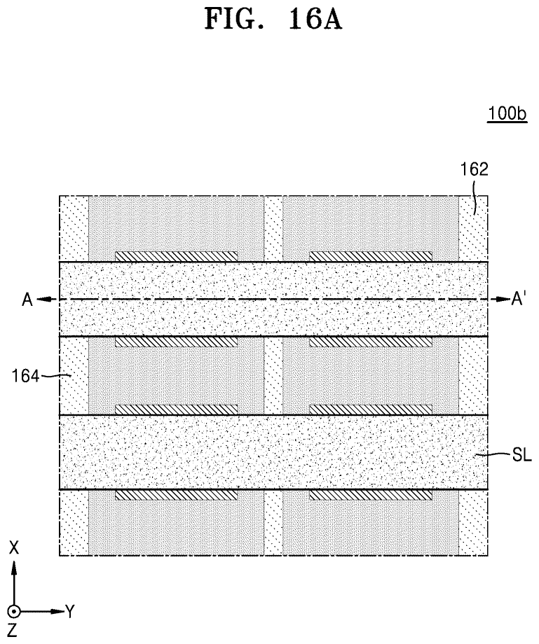

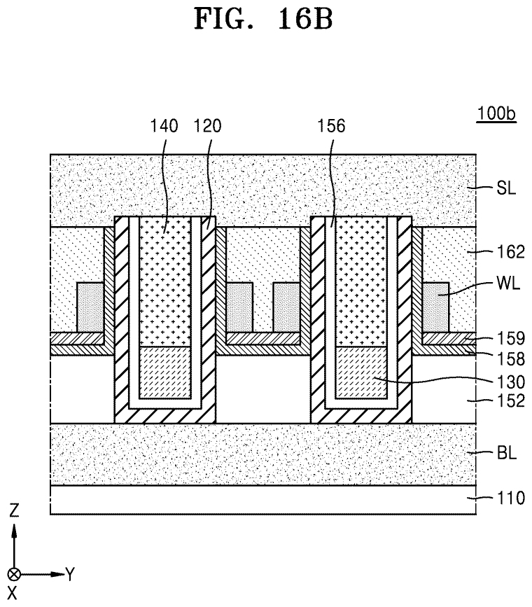

Referring to FIGS. 16A and 16B, the selection line SL may be formed on the resulting structure of FIGS. 15A and 15B. A plurality of selection lines SL may be formed at positions where the selection lines SL overlap the plurality of bit lines BL in the vertical direction (the Z direction), extend in the second horizontal direction (the Y direction), and may be spaced apart from each other in the first horizontal direction (the X direction). In some embodiments, a space where the plurality of the selection lines SL are not formed may be at least partially filled with a buried insulating layer 164. Through processes described above, the semiconductor memory device 100b including a vertical channel structure may be formed.

The semiconductor memory device 100 b of FIGS. 16A and 16B may have a 2T memory cell structure similar to the semiconductor memory devices 100 and 100A described above, and may store information in the storage node 130 instead of a capacitor, so a high device integration may be expected. In addition, the word line WL may be formed in the form of GAA, and the semiconductor memory device 100b may have a structure in which the first channel layer 120 at least partially surrounds the second channel layer 140 in the ‘U’ shape (or in the ‘C’ shape depending on the orientation thereof).

In some embodiments, one end of the first channel layer 120 may contact the bit line BL, and the other end may contact the selection line SL. One end of the second channel layer 140 may contact the selection line SL, and the other end thereof may contact the storage node 130.

The semiconductor memory device 100b of FIGS. 16A and 16B may have the VCT structure. Specifically, the semiconductor memory device 100b may include the bit line BL extending in a direction parallel to the upper surface of the substrate 110, the selection line SL arranged to vertically (Z direction) overlap the bit line BL at a vertical level higher than the bit line BL where the substrate 110 provides a base reference plane, the first channel layer 120 arranged between the bit line BL and the selection line SL, the second channel layer 140 at least partially surrounded on three sides by the first channel layer 120, and the word line WL in the form of GAA.

As described above, embodiments have been disclosed in the drawings and specification. Although specific terms have been used to describe embodiments in this specification, they are used only for the purpose of explaining the inventive concept and are not intended to limit the meaning or the scope of the inventive concept set forth in the claims. Therefore, those skilled in the art will understand that various modifications and equivalent embodiments are possible from embodiments disclosed herein. Therefore, the scope of the inventive concept should be determined by the appended claims.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a memory cell arranged on a substrate in three dimensions along a first direction, a second direction orthogonal to the first direction, and a third direction, the memory cell comprising a first transistor that comprises a first channel layer and a second transistor that comprises a second channel layer;
a bit line electrically connected to a first end of the first channel layer and extending in the third direction;
a selection line electrically connected to a second end of the first channel layer and extending in the third direction;
a storage node directly contacting a first surface of the second channel layer and positioned adjacent to the first channel layer; and
a word line at least partially surrounding the other end of the first channel layer in the first direction and the second direction between the bit line and the selection line, and extending in the first direction,
wherein the word line has a cross-section that surrounds the second end of the first channel layer and the second channel layer in a ring shape in a plane defined by the first direction and the third direction, and
wherein the first channel layer has a ‘C’ shape in a plane defined by the second direction and the third direction, and the storage node and the second channel layer are arranged inside the ‘C’ shape of the first channel layer.

2. The semiconductor memory device of claim 1, wherein
the first transistor comprises a read transistor, and the second transistor comprises a write transistor.

3. The semiconductor memory device of claim 1, wherein
the first transistor comprises an n-channel metal oxide semiconductor (NMOS) transistor, and the second transistor comprises an NMOS transistor or a p-channel MOS (PMOS) transistor.

4. The semiconductor memory device of claim 1, wherein
a second surface opposite to the first surface of the second channel layer directly contacts the selection line.

5. The semiconductor memory device of claim 1, wherein
the first channel layer comprises a vertical extension portion, a first horizontal extension portion connected to one end of the vertical extension portion, and a second horizontal extension portion connected to the other end of the vertical extension portion, and
a thickness of the first horizontal extension portion is the same as a thickness of the second horizontal extension portion, and a thickness of the vertical extension portion is less than the thickness of the first horizontal extension portion and the thickness of the second horizontal extension portion.

6. The semiconductor memory device of claim 1, wherein
the first channel layer comprises a vertical extension portion, a first horizontal extension portion connected to one end of the vertical extension portion, and a second horizontal extension portion connected to the other end of the vertical extension portion, and
thicknesses of the first horizontal extension portion, the second horizontal extension portion, and the vertical extension portion are equal to each other.

7. The semiconductor memory device of claim 1, wherein
one end of the bit line directly contacts the substrate and another end thereof is electrically connected to a first metal line via a first pad,
one end of the selection line directly contacts the substrate and another end thereof is electrically connected to a second metal line via a second pad, and the first metal line and the second metal line extend in the second direction.

8. The semiconductor memory device of claim 1, further comprising
a gate dielectric film arranged between the first channel layer and the storage node, and between the first channel layer and the second channel layer.

9. The semiconductor memory device of claim 1, wherein
the first channel layer and the second channel layer each comprise an oxide semiconductor, polysilicon, a two-dimensional (2D) material semiconductor, or a combination thereof.

10. The semiconductor memory device of claim 1, wherein
the storage node comprises a floating gate of the first transistor.

11. A semiconductor memory device comprising:
a bit line extending in a second direction that intersects a first direction on a substrate;
a first channel layer having a ‘U’ shape in a plane defined by the second direction and a third direction perpendicular to an upper surface of the substrate, the first channel layer comprising a horizontal extension portion that directly contacts an upper surface of the bit line and a vertical extension portion extending in the third direction from an end of the horizontal extension portion;
a second channel layer inside the ‘U’ shape of the first channel layer, the second channel layer comprising an upper surface that is coplanar with an upper surface of the vertical extension portion and a lower surface opposite to the upper surface;
a storage node comprising a first surface and a second surface opposite to the first surface, wherein the first surface directly contacts an upper surface of the horizontal extension portion of the first channel layer, and the second surface directly contacts the lower surface of the second channel layer;
a word line extending in the first direction and at least partially surrounding a side surface of the vertical extension portion of the first channel layer in a ring shape in the first direction and the second direction; and
a selection line that directly contacts the upper surface of the second channel layer and overlaps the bit line in the third direction.

12. The semiconductor memory device of claim 11, wherein
the semiconductor memory device comprises a first transistor and a second transistor, wherein the first transistor comprises the first channel layer, and the second transistor comprises the second channel layer.

13. The semiconductor memory device of claim 12, wherein
the first transistor comprises a read transistor, and the second transistor comprises a write transistor.

14. The semiconductor memory device of claim 11, wherein
an upper surface of the word line is farther from the substrate than the lower surface of the second channel layer and closer to the substrate than the upper surface of the second channel layer.

15. The semiconductor memory device of claim 11, further comprising
a cover insulating layer at least partially surrounding a side surface of the vertical extension portion between the vertical extension portion of the first channel layer and the word line.

16. A semiconductor memory device comprising:
a plurality of memory cells arranged on a substrate in three dimensions along a first direction, a second direction orthogonal to the first direction, and a third direction, each memory cell of the plurality of memory cells comprising a first transistor and a second transistor;
a plurality of bit lines each extending in the third direction;
a plurality of selection lines each extending in the third direction;
a first channel layer included in the first transistor;
a second channel layer included in the second transistor; and
a storage node,
wherein the first channel layer comprises a vertical extension portion extending in the third direction and directly contacting one bit line of the plurality of bit lines, and a horizontal extension portion extending in the second direction from both ends of the vertical extension portion toward one selection line of the plurality of selection lines, and the horizontal extension portion is electrically connected to the one selection line,
wherein the second channel layer is at least partially surrounded by the horizontal extension portion of the first channel layer, and comprises a first surface directly contacting the one selection line and a second surface facing the horizontal extension portion of the first channel layer,
wherein the storage node is at least partially surrounded by the horizontal extension portion of the first channel layer, and comprises a first surface directly contacting the second surface of the second channel layer and a second surface facing the horizontal extension portion of the first channel layer,
wherein the semiconductor memory device further comprises a word line at least partially surrounding the horizontal extension portion of the first channel layer in the first direction and the second direction between the one bit line and the one selection line, and extending in the first direction, and
wherein the word line has a cross-section that surrounds the horizontal extension portion of the first channel layer and the second channel layer in a ring shape in a plane defined by the first direction and the third direction.

17. The semiconductor memory device of claim 16, wherein
the first transistor comprises a read transistor, and the second transistor comprises a write transistor.

18. The semiconductor memory device of claim 16, wherein
one end of the one bit line directly contacts the substrate and the other end thereof is electrically connected to a first metal line via a first pad,
one end of the one selection line directly contacts the substrate and the other end thereof is electrically connected to a second metal line via a second pad, and the first metal line and the second metal line extend in the second direction.

19. The semiconductor memory device of claim 16, wherein
the first channel layer and the second channel layer each comprise an oxide semiconductor, polysilicon, a two-dimensional (2D) material semiconductor, or a combination thereof.

20. The semiconductor memory device of claim 16, wherein
a width of the vertical extension portion of the first channel layer is not greater than a width of the horizontal extension portion of the first channel layer.
